(19) United States
(12) Patent Application Publication
(10) Pub. No.: US 2012/0103417 A1
(43) Pub. Date: May 3, 2012

(54) SOLAR CELL WITH GRADED BANDGAP

(75) Inventors: Kuang-Chen YEH, Jhunan Township (TW); Chu-Wan HUANG, Tucheng City (TW); Jr-Hong CHEN, ShenZhen City (CN)

(73) Assignee: Du Pont Apollo Limited, Hong Kong (HK)

(21) Appl. No.: 12/915,065

(22) Filed: Oct. 29, 2010

(51) Int. Cl. H01L 31/0264; H01L 31/02

(52) U.S. Cl. 136/258; 136/252

(57) ABSTRACT

A solar cell with graded bandgap is provided to increase the efficiencies of using the solar energy by a solar cell. The solar cell with graded bandgap above sequentially comprises a transparent conductive layer, a polysilicon layer, and conductive layer on a substrate. The polysilicon layer has a gradually increased bandgap from a first interface contacting the transparent conductive layer to the second interface contacting the conductive layer.

### BACKGROUND

1. Technical Field

The disclosure relates to a solar cell. More particularly, the disclosure relates to solar cell with graded bandgap.

2. Description of Related Art

It is well known that the most efficient conversion of radiant energy to electrical energy with the least thermalization loss in semiconductor materials is accomplished by matching the photon energy of the incident radiation to the amount of energy needed to excite electrons in the semiconductor material to transcend the bandgap from the valence band to the conduction band. However, since solar radiation usually comprises a wide range of wavelengths, use of only one semiconductor material with only one band gap to absorb such radiant energy and convert it to electrical energy results in large inefficiencies and energy losses to unwanted heat. Accordingly, how to increase the efficiencies of using the solar energy to decrease the energy losses is an important issue in the solar cell industry.

### SUMMARY

According to an embodiment of this invention, a solar cell with graded bandgap is provided to increase the efficiencies of using the solar energy by a solar cell.

The solar cell with graded bandgap above sequentially comprises a transparent conductive layer, a polysilicon layer, and a conductive layer on a substrate. The polysilicon layer has a gradually decreased bandgap from a first interface contacting the transparent conductive layer to the second interface contacting the conductive layer.

The polysilicon layer is formed by metal induced crystallization of a multilayered structure comprising alternately arranged amorphous silicon layers and metal layers containing Ni. The Ni densities in the metal layers are gradually increased from the first metal layer near the first interface to the last metal layer near the second interface to gradually increased the grain sizes of the polysilicon layer.

It is to be understood that both the foregoing general description and the following detailed description are by examples, and are intended to provide further explanation of the invention as claimed.

### BRIEF DESCRIPTION OF THE DRAWINGS

FIG. 1 is a cross-sectional diagram of a solar cell according to one embodiment of this invention.

FIG. 2 is an enlarged cross-sectional diagram of a multilayered structure for forming the polysilicon layer 120 in FIG. 1 according to an embodiment.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

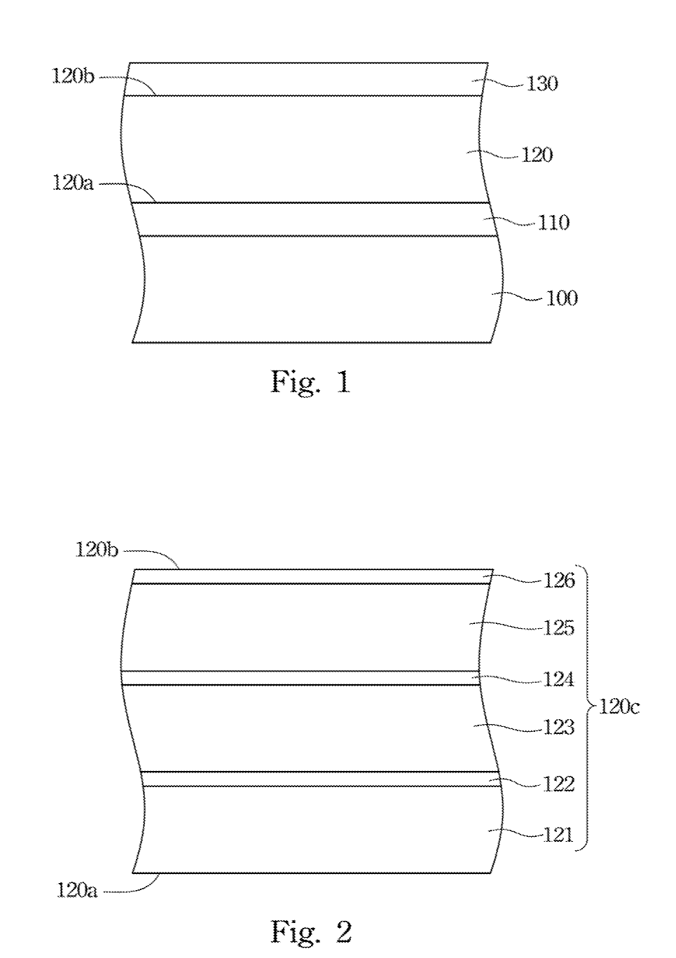

FIG. 1 is a cross-sectional diagram of a solar cell according to one embodiment of this invention. In FIG. 1, the solar cell has a transparent conductive layer 110, a polysilicon layer 120, and a conductive layer 130 sequentially on a transparent substrate 100. The material of the transparent substrate 100 can be glass, or quartz, for example. The material of the transparent conductive layer 110 can be transparent metal oxides, such as PbO₂, CdO, Tl₂O₃, Ga₂O₃, ZnPb₂O₆, CdIn₂O₄, MgIn₂O₄, ZnGaO₄, AgSbO₃, CuAlO₂, CuGaO₂, CdO—Ge02 PbO₂, I₂O₃, Ga₂O₃, ZnPb₂O₆, CdIn₂O₄, MgIn₂O₄, ZnGaO₄, AgSbO₃, CuAlO₂, CuGaO₂, CdO—GeO₂, AZO (ZnO: Al) GZO (ZnO: Ga), ATO (SnO₂:Sb), FTO (SnO₂:F), ITO (In₂O₃:Sn), or BaTiO₃, for example. The material of the conductive layer 130 can be transparent metal oxides above or metal, such as Al, Ag, Ti or Cu, for example. The light entering site of the solar cell in FIG. 1 is at the transparent substrate 100.

The bandgap of the polysilicon layer 120 in FIG. 1 is gradually decreased from the first interface 120a contacting the transparent conductive layer 110 to the second interface 120b contacting the conductive layer 130. Since the bandgap of polysilicon is decreased with the increase of the polysilicon's grain size, the grain-size distribution of the polysilicon layer 120 is also gradually increased from the first interface 120a to the second interface 120b. Therefore, the absorbable light wavelengths by the polysilicon layer 120 can be accordingly changed with the graded bandgap.

The above polysilicon layer 120 with graded bandgap can be formed by the following method, for example. First, a multilayered structure, comprising alternately arranged amorphous silicon layers and metal layers, is formed on the transparent conductive layer 110 in FIG. 1. Next, an anneal process is performed to crystallize the amorphous silicon layer to the polysilicon layer 120 with gradually-changed grain size in FIG. 1 by metal induced crystallization (MIC). The grain size of the polysilicon layer 120 can be controlled by the metal density in the metal layer.

For example, FIG. 2 is an enlarged cross-sectional diagram of a multilayered structure for forming the polysilicon layer 120 in FIG. 1 according to an embodiment. In FIG. 2, the multilayered structure 120c comprises three amorphous silicon layers 121, 123, 125, and three metal layers 122, 124, 126 arranged alternately. The three amorphous silicon layers 121, 123, 125 can be formed by chemical vapor deposition. The three metal layers 122, 124, 126 are formed by coating a metal solution with gradually increased metal concentration from the first interface 120a to the second interface 120b. The metal can be Ni, for example.

The Ni solution can be prepared by dissolving Ni in an acid solution, such as HNO₃ solution or HCl solution, and the anneal temperature can be 500-800° C. The Ni concentration of the Ni solution is about 1,000-10,000 ppm to change the grain size of polysilicon after the anneal process. For example, the Ni concentrations of the Ni solution for forming the metal layers 122, 124, and 126 can be adjusted to low, middle, and high concentrations to let the final polysilicon crystallized from the amorphous silicon layer 121, 123, 125 respectively absorb 300-600 nm, 600-900 nm, and 900-1100 nm of light.

Alternatively, the Ni solution can also be prepared by dissolving Ni and a second metal, such as Au or Pd, dissolving in an acid solution, such as HNO₃ solution or HCl solution, and the anneal temperature can be 470-800° C. The Ni concentration of the Ni solution is about 1,000-10,000 ppm to change the grain size of the polysilicon after the anneal process, and the concentration of the second metal is about 500 ppm. Similarly, the Ni concentrations of the Ni solution for forming the metal layers 122, 124, and 126 can also be adjusted to low, middle, and high concentrations to let the final polysilicon crystallized from the amorphous silicon layer 121, 123, 125 respectively absorb 300-600 nm, 600-900 nm, and 900-1000 nm of light.

Accordingly, a solar cell with graded bandgap can be formed by metal induced crystallization. Therefore, the efficiencies of using the solar energy can be increased to decrease the energy losses by the solar cell.

The reader's attention is directed to all papers and documents which are filed concurrently with his specification and which are open to public inspection with this specification, and the contents of all such papers and documents are incorporated herein by reference.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

What is claimed is:

1. A solar cell with graded bandgap, comprising:
a transparent conductive layer on a substrate;
a conductive layer above the transparent conductive layer; and
polysilicon layer between the transparent conductive layer and the conductive layer, wherein the polysilicon layer has a gradually decreased bandgap from a first interface contacting the transparent conductive layer to the second interface contacting the conductive layer.

2. The solar cell of claim 1, wherein the polysilicon layer is formed by metal induced crystallization of a multilayered structure comprising alternately arranged amorphous silicon layers and metal layers containing Ni, and the Ni densities in the metal layers are gradually increased from the first metal layer near the first interface to the last metal layer near the second interface to gradually increase the grain sizes of the polysilicon layer.

3. The solar cell of claim 2, wherein the metal layers are formed by coating a Ni solution formed by dissolving Ni in an acidic solution.

4. The solar cell of claim 3, wherein the acidic solution is HNO₃ solution or HCl solution.

5. The solar cell of claim 2, wherein the metal layers are formed by coating a Ni solution formed by dissolving Ni/Au or Ni/Pd in an acidic solution.

6. The solar cell of claim 5, wherein the acidic solution is HNO₃ solution or HCl solution.

7. The solar cell of claim 2, wherein an anneal temperature of the metal induced metallization is about 470-800° C.
